(19) United States
(12) Patent Application Publication
(10) Pub. No.: US 2020/0075251 A1
(43) Pub. Date: Mar. 5, 2020

(54) MULTILAYER CERAMIC ELECTRONIC COMPONENT

(71) Applicant: Samsung Electro-Mechanics Co., Ltd., Suwon-si (KR)

(72) Inventors: Kyung Il Park, Suwon-si (KR); Bum Chul Bae, Suwon-si (KR)

(21) Appl. No.: 16/259,507

(22) Filed: Jan. 28, 2019

Related U.S. Application Data
(63) Continuation of application No. 16/178,237, filed on Nov. 1, 2018.

(30) Foreign Application Priority Data
Sep. 5, 2018 (KR) 10-2018-0105914

(51) Int. Cl. H01G 4/248; H01G 4/008; H05K 1/11; H05K 1/18; H01G 4/30; H01G 4/12; H01G 4/012

(52) U.S. Cl. CPC H01G 4/248; H01G 4/008; H05K 1/11; H05K 2201/10015; H01G 4/30; H01G 4/1227; H01G 4/012; H05K 1/181

(57) ABSTRACT

A multilayer ceramic electronic component includes: a ceramic body including a dielectric layer and first and second internal electrodes stacked to be alternately exposed to one side surface and the other side surface with the dielectric layer disposed therebetween; and first and second external electrodes disposed on outer surfaces of the ceramic body to be connected to the first and second internal electrodes, respectively, in which the first and second external electrodes include first and second nickel plating layer having a nickel fineness of 89% or more and 93% or less, respectively.

### CROSS-REFERENCE TO RELATED APPLICATION(S)

This application is a continuation of U.S. patent application Ser. No. 16/178,237, filed on Nov. 1, 2018 which claims benefit of priority to Korean Patent Application No. 10-2018-0105914 filed on Sep. 5, 2018 in the Korean Intellectual Property Office, the disclosures of which are incorporated herein by reference in their entireties.

### TECHNICAL FIELD

The present disclosure relates to a multilayer ceramic electronic component.

### BACKGROUND

A multilayer ceramic electronic component has been widely used as an information technology (IT) component of a computer, a personal digital assistant (PDA), a cellular phone, and the like, since it has a small size, implements high capacitance, may be easily mounted, and has been widely used as an electrical component, since it has high reliability and high durability characteristics.

An external electrode included in the multilayer ceramic electronic component is an electrode exposed externally of the multilayer ceramic electronic component, and thus has a significant influence on reliability and durability of the multilayer ceramic electronic component.

### SUMMARY

An aspect of the present disclosure may provide a multilayer ceramic electronic component having improved reliability of external electrodes and improved mounting reliability by optimizing a nickel fineness of nickel plating layers included in the external electrodes.

According to an aspect of the present disclosure, a multilayer ceramic electronic component may include: a ceramic body including a dielectric layer and first and second internal electrodes stacked to be alternately exposed to one side surface and the other side surface with the dielectric layer disposed therebetween; and first and second external electrodes disposed on outer surfaces of the ceramic body to be connected to the first and second internal electrodes, respectively, in which each of the first and second external electrodes may include first and second nickel plating layers having a nickel fineness of 89% or more and 93% or less.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a perspective view showing a multilayer ceramic electronic component according to an exemplary embodiment of the present disclosure;

FIG. 2 is a cross-sectional view taken along line A-A′ of FIG. 1;

FIG. 3 is an enlarged view of region S of FIG. 2;

FIG. 4 is a perspective view showing a mounting form of a multilayer ceramic electronic component according to an exemplary embodiment of the present disclosure;

FIG. 5A is an SEM diagram showing a nickel plating layer having a nickel fineness of 99%;

FIG. 5B is an SEM diagram showing a nickel plating layer having a nickel fineness of 95%;

FIG. 5C is an SEM diagram showing a nickel plating layer having a nickel fineness of 92%;

FIG. 5D is an SEM diagram showing a nickel plating layer having a nickel fineness of 81%;

FIG. 5E is an SEM diagram showing a form in which the nickel plating layer having a nickel fineness of 99% swells up;

FIG. 5F is an SEM diagram showing a form in which the nickel plating layer having a nickel fineness of 92% does not swell up;

FIG. 5G is an SEM diagram showing a case in which the nickel plating layer having a nickel fineness of 95% is in a good mounting state; and

FIG. 5H is an SEM diagram showing a case in which the nickel plating layer having a nickel fineness of 81% is in a poor mounting state.

### DETAILED DESCRIPTION

Hereinafter, exemplary embodiments of the present disclosure will now be described in detail with reference to the accompanying drawings.

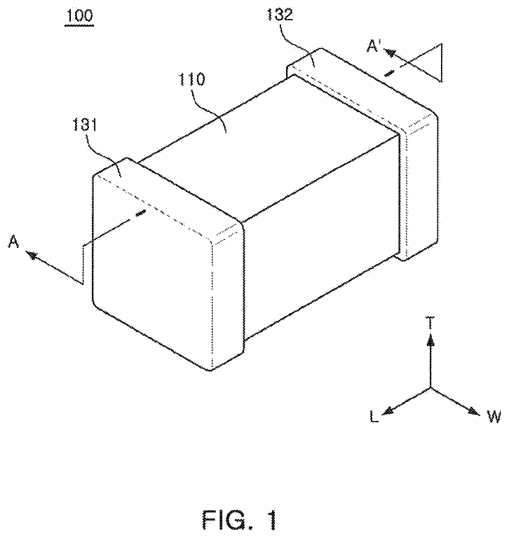

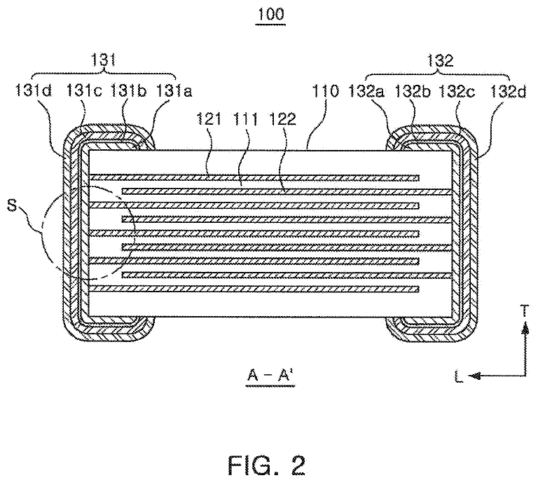

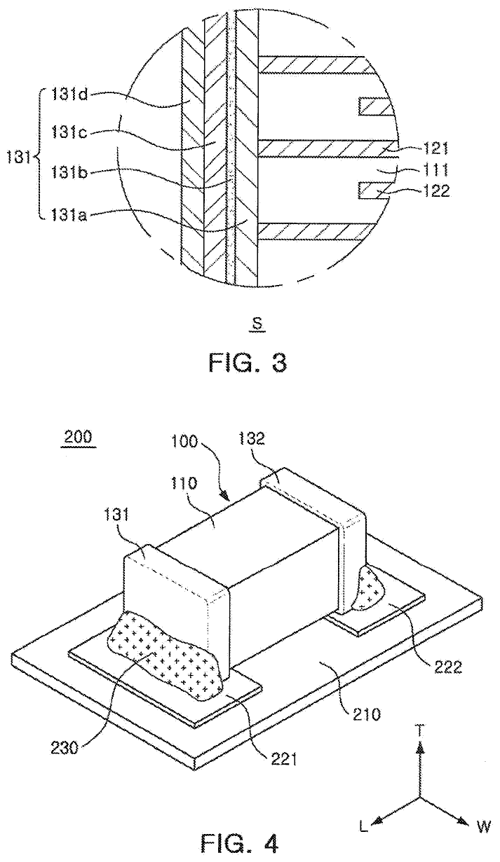

FIG. 1 is a perspective view showing a multilayer ceramic electronic component according to an exemplary embodiment of the present disclosure, FIG. 2 is a cross-sectional view taken along line A-A′ of FIG. 1, and FIG. 3 is an enlarged view of region S of FIG. 2.

Referring to FIGS. 1 through 3, a multilayer ceramic electronic component 100 according to an exemplary embodiment of the present disclosure may include a ceramic body 110 and first and second external electrodes 131 and 132.

The ceramic body 110 may be formed in a hexahedron having both side surfaces in a length direction L, both side surfaces in a width direction W, and both side surfaces in a thickness direction T. The ceramic body 110 may be formed by stacking a plurality of dielectric layers 111 in the thickness direction T and then sintering the plurality of dielectric layers 111. A shape and a dimension of the ceramic body 110 and the number (one or more) of stacked dielectric layers 111 are not limited as shown in the exemplary embodiment of the present disclosure.

The plurality of dielectric layers 111 disposed in the ceramic body 110 may be in a sintered state. Adjacent dielectric layers 111 may be integrated with each other so that boundaries therebetween are not readily apparent without using a scanning electron microscope (SEM).

For example, the ceramic body 110 may be formed in a hexahedron having eight rounded vertexes. Accordingly, durability and reliability of the ceramic body 110 may be improved, and structural reliability of the first and second external electrodes 131 and 132 at the vertexes may be improved.

A thickness of the dielectric layer 111 may be arbitrarily changed in accordance with a capacity design of the multilayer ceramic capacitor 100, and the dielectric layer 111 may include high-k ceramic powders, for example, barium titanate (BaTiO₃) based powders or strontium titanate (SrTiO₃) based powders. However, the material of the dielectric layer 111 is not limited thereto. In addition, for the purpose of the present disclosure, various ceramic additives, organic solvents, plasticizers, binders, dispersants and the like may be added to the ceramic powders.

An average particle size of the ceramic powder used to form the dielectric layer 111 is not particularly limited, but may be adjusted in order to accomplish an object of the present disclosure. For example, the average particle size of the ceramic powder may be adjusted to be 400 nm or less.

For example, the dielectric layer 111 may be formed by applying slurry formed of a powder, such as barium titanate (BaTiO₃), to a carrier film and drying the slurry to prepare a plurality of ceramic sheets. The ceramic sheet may be manufactured by mixing the ceramic powder, the binder, and the solvent to produce a slurry and producing the slurry in a sheet form having a thickness of several Pm by a doctor blade method, but the manufacturing method of the ceramic sheet is not limited thereto.

First and second internal electrodes 121 and 122 may have at least one first internal electrode 121 and at least one second internal electrode 122 having different polarities from each other and may be formed to have a predetermined thickness with the plurality of dielectric layers 111 stacked in the thickness direction T of the ceramic body 110 disposed therebetween.

The first internal electrode 121 and the second internal electrode 122 may be formed by printing a conductive paste including a conductive metal so as to be alternately exposed to one side and the other side in the length direction L of the ceramic body 110 along a stacked direction of the dielectric layer 111 and may be electrically insulated from each other by the dielectric layer 111 disposed therebetween.

That is, the first and second internal electrodes 121 and 122 may be electrically connected to each of the first and second external electrodes 131 and 132 formed on both side surfaces in the length direction of the ceramic body 110 through the parts alternately exposed to both side surfaces in the length direction of the ceramic body 110.

For example, the first and second internal electrodes 121 and 122 may be formed of a conductive paste for internal electrodes including a conductive metal powder having an average particle size of 0.1 to 0.2 μm and 40 to 50% by weight, but the first and second internal electrodes 121 and 122 are not necessarily formed as described above.

The conductive paste for the internal electrodes may be applied on the ceramic sheet by a printing method or the like to form an internal electrode pattern. As a method of printing the conductive paste, a screen printing method, a gravure printing method or the like may be used. However, the method of printing the conductive paste is not limited thereto. The ceramic sheet on which the internal electrode pattern is printed may be stacked by 200 to 300 layers and then compressed and sintered to manufacture the ceramic body 110.

Therefore, if a voltage is applied to the first and second external electrodes 131 and 132, charges may be accumulated between the first and second internal electrodes 121 and 122 facing each other. In this case, the capacitance of the multilayer ceramic capacitor 100 may be in proportion to an area of a region in which the first and second internal electrodes 121 and 122 overlap each other.

That is, when the area of the region in which the first and second internal electrodes 121 and 122 overlap each other is as large as possible, the capacitance may be as large as possible even in capacitors of the same size.

The widths of the first and second internal electrodes 121 and 122 may be determined depending on the usage thereof. For example, the widths of the first and second internal electrodes 121 and 122 may be determined to be in the range of 0.2 to 1.0 mm in consideration of the size of the ceramic body 110. However, the range of the widths of the first and second internal electrodes 121 and 122 may not be limited thereto.

Since the thickness of the dielectric layer 111 corresponds to a gap between the first and second internal electrodes 121 and 122, the capacitance of the multilayer ceramic electronic component 100 may be increased as the thickness of the dielectric layer 111 is decreased.

Withstand voltage characteristics of the ceramic body 110 may be improved as the gap between the first and second internal electrodes 121 and 122 is increased.

If the multilayer ceramic electronic component 100 requires high withstand voltage characteristics like the electrical component, the multilayer ceramic electronic component 100 may be designed so that an average thickness of the dielectric layer 111 exceeds twice that of the first and second internal electrodes 121 and 122. Accordingly, the multilayer ceramic electronic component 100 has the high withstand voltage characteristics and thus may be used as the electrical component.

Meanwhile, the conductive metal included in the conductive paste forming the first and second internal electrodes 121 and 122 may be formed of nickel (Ni), copper (Cu), palladium (Pd), silver (Ag), lead (Pb), platinum (Pt) or the like, alone or an alloy thereof. However, the conductive metal is not limited thereto.

Each of the first and second external electrodes 131 and 132 may be disposed at outer surfaces of the ceramic body 110 so as to be connected to the first and second internal electrodes 121 and 122, and may be configured to electrically connect between the substrate and the first and second internal electrodes 121 and 122, respectively.

The first and second external electrodes 131 and 132 may include first and second nickel plating layers 131c and 132c for at least some of structural reliability, easiness of mounting on a substrate, durability against the outside, heat resistance, and equivalent series resistance (ESR).

The first and second nickel plating layers 131c and 132c may be formed according to a process accompanied by a plating solution, hydrogen gas, and moisture, as in sputtering or electric deposition. Accordingly, the hydrogen gas and the moisture may penetrate into inner regions of the first and second nickel plating layers 131c and 132c in the first and second external electrodes 131 and 132.

If the nickel fineness of the first and second nickel plating layers 131c and 132c is high, the hydrogen gas and the moisture penetrating into the inner regions of the first and second nickel plating layers 131c and 132c may not be discharged to the outside of first and second external electrodes 131 and 132 due to high nickel fineness of the first and second nickel plating layers 131c and 132c. The hydrogen gas and the moisture which are not discharged to the outside of the first and second external electrodes 131 and 132 may be expanded later to lower the structural reliability of the first and second external electrodes 131 and 132. Here, nickel fineness refers to the weight of nickel in proportion to the total weight of nickel and any impurities other than nickel in a corresponding nickel plating layer.

The multilayer ceramic electronic device 100 according to an exemplary embodiment of the present disclosure may include the first and second nickel plating layers 131c and 132c having the nickel fineness enough to discharge the hydrogen gas and the moisture of the first and second external electrodes 131 and 132 to the outside, thereby preventing the nickel plating layers 131c and 132c from swelling up later due to the hydrogen gas and the moisture, thereby improving the structural reliability of the first and second external electrodes 131 and 132.

The following Table 1 shows an external electrode swelling defect rate according to the nickel fineness of the first and second nickel plating layers 131c and 132c.

TABLE 1

| | Head surface part test result | | | Solderability part test result | | |
|---|---|---|---|---|---|---|
| | The | The | Defec- | The | The | Defec- |
| Ni | number | number | tive | number | number | tive |
| density | of tests | of NGs | rate | of tests | of NGs | rate |
| 81% | 100 | 0 | 0.0% | 100 | 35 | 35.0% |
| 82% | 100 | 0 | 0.0% | 100 | 31 | 31.0% |
| 83% | 100 | 0 | 0.0% | 100 | 24 | 24.0% |
| 84% | 100 | 0 | 0.0% | 100 | 13 | 13.0% |
| 85% | 100 | 0 | 0.0% | 100 | 7 | 7.0% |
| 86% | 100 | 0 | 0.0% | 100 | 4 | 4.0% |
| 87% | 100 | 0 | 0.0% | 100 | 3 | 3.0% |
| 88% | 100 | 0 | 0.0% | 100 | 1 | 1.0% |
| 89% | 100 | 0 | 0.0% | 100 | 0 | 0.0% |
| 90% | 100 | 0 | 0.0% | 100 | 0 | 0.0% |
| 91% | 100 | 0 | 0.0% | 100 | 0 | 0.0% |
| 92% | 100 | 0 | 0.0% | 100 | 0 | 0.0% |
| 93% | 100 | 0 | 0.0% | 100 | 0 | 0.0% |
| 94% | 100 | 2 | 2.0% | 100 | 0 | 0.0% |
| 95% | 100 | 2 | 2.0% | 100 | 0 | 0.0% |
| 96% | 100 | 3 | 3.0% | 100 | 0 | 0.0% |
| 97% | 100 | 7 | 7.0% | 100 | 0 | 0.0% |
| 98% | 100 | 9 | 9.0% | 100 | 0 | 0.0% |
| 99% | 100 | 26 | 26.0% | 100 | 0 | 0.0% |

Referring to the above Table 1, if the nickel fineness of the first and second nickel plating layers 131c and 132c is 93% or less, the first and second nickel plating layers 131c and 132c may prevent the external electrode swelling defect.

Meanwhile, if the nickel fineness of the first and second nickel plating layers 131c and 132c is too low, the first and second nickel plating layers 131c and 132c may cause a defect (for example, solder disconnection) upon mounting.

Referring to the above Table 1, if the nickel fineness of the first and second nickel plating layers 131c and 132c are 89% or more, the first and second nickel plating layers 131c and 132c may prevent soldering defect upon mounting.

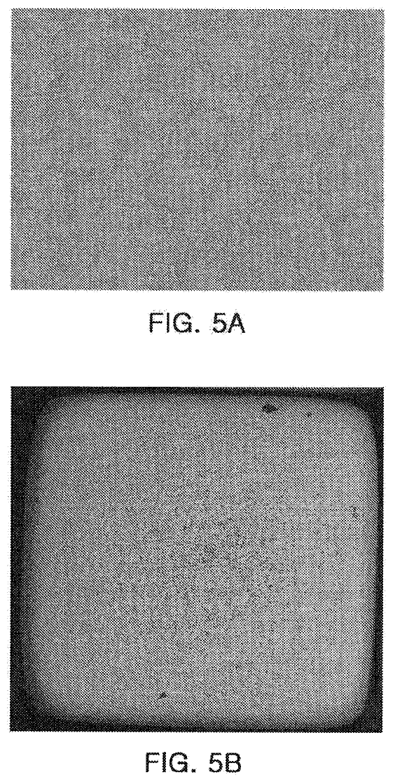

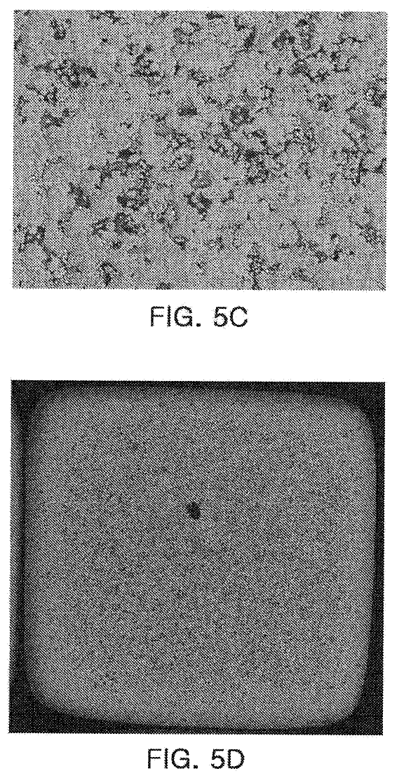

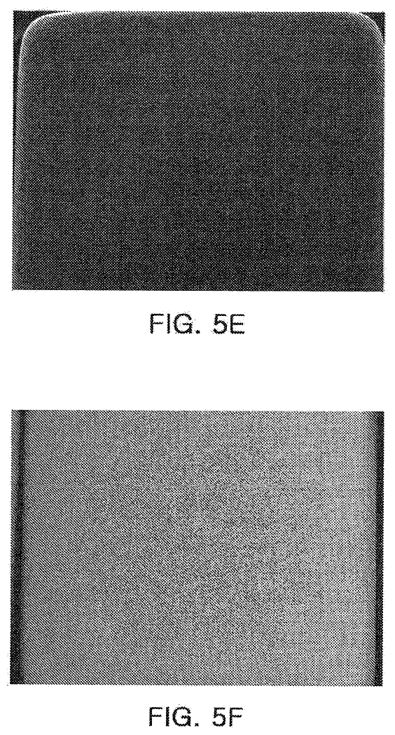

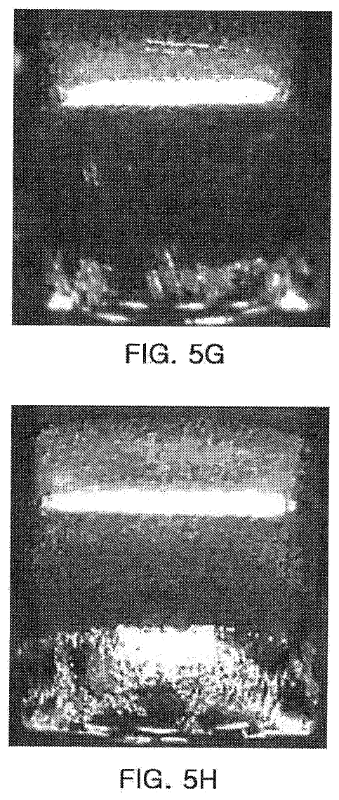

Some results of the above examples in Table 1 are shown in FIGS. 5A-5H. For example, FIG. 5A is an SEM diagram showing a nickel plating layer having a nickel fineness of 99%, FIG. 5B is an SEM diagram showing a nickel plating layer having a nickel fineness of 95%, FIG. 5C is an SEM diagram showing a nickel plating layer having a nickel fineness of 92%, FIG. 5D is an SEM diagram showing a nickel plating layer having a nickel fineness of 81%, FIG. 5E is an SEM diagram showing a form in which the nickel plating layer having a nickel fineness of 99% swells up, FIG. 5F is an SEM diagram showing a form in which the nickel plating layer having a nickel fineness of 92% does not swell up, FIG. 5G is an SEM diagram showing a case in which the nickel plating layer having a nickel fineness of 95% is in a good mounting state, and FIG. 5H is an SEM diagram showing a case in which the nickel plating layer having a nickel fineness of 81% is in a poor mounting state.

Therefore, the multilayer ceramic electronic component 100 according to the exemplary embodiment of the present disclosure includes the first and second nickel plating layers having a nickel fineness of 89% or more and 93% or less, thereby preventing the external electrode swelling defect and the defect upon mounting.

Meanwhile, the first and second external electrodes 131 and 132 may further include first and second base electrode layers 131a and 132a which are disposed between the first and second internal electrodes 121 and 122 and the first and second nickel plating layers 131c and 132c and at least partially contact the external surface of the ceramic body 110.

The first and second base electrode layers 131a and 132a may be easily coupled to the first and second internal electrodes 121 and 122 relative to the first and second nickel plating layers 131c and 132c, such that a contact resistance to the first and second internal electrodes 121 and 122 may be reduced.

The first and second base electrode layers 131a and 132a may be disposed in the inner regions of the first and second nickel plating layers 131c and 132c in the first and second external electrodes 131 and 132.

For example, first and second base electrode layers 131a and 132a may be covered with the first and second nickel plating layers 131c and 132c and first and second conductive layers 131b and 132b so as not to be exposed to the outside of the multilayer ceramic electronic component 100.

Moisture may be distributed on the surfaces of the first and second base electrode layers 131a and 132a according to pretreatment washing before the first and second nickel plating layers 131c and 132c are formed.

The multilayer ceramic electronic component 100 according to the exemplary embodiment of the present disclosure may be configured so that the moisture distributed on the surfaces of the first and second base electrode layers 131a and 132a is discharged to the outside through the first and second nickel plating layers 131c and 132c. Therefore, the external electrode swelling defect may be prevented.

For example, the first and second base electrode layers 131a and 132a may be formed by a method of dipping a paste including a metal component or a method of printing a conductive paste including a conductive metal on at least one surface in the thickness direction T of the ceramic body 110, and may also be formed by a sheet transfer method and a pad transfer method.

For example, the first and second base electrode layers 131a and 132a may be formed of copper (Cu), nickel (Ni), palladium (Pd), platinum (Pt), gold (Au), silver (Ag), lead (Pb) or the like, alone or an alloy thereof.

Meanwhile, the first and second external electrodes 131 and 132 may further include first and second conductive resin layers 131b and 132b which are disposed between the first and second base electrode layers 131a and 132a and the first and second nickel plating layers 131c and 132c, respectively.

Since the first and second conductive resin layers 131b and 132b have relatively higher flexibility than the first and second nickel plating layers 131c and 132c, the first and second conductive resin layers 131b and 132b may protect external physical impact or bending impact of the multilayer ceramic electronic component 100 and prevent the external electrode from being cracked by absorbing a stress or a tensile stress applied upon being mounted on the substrate.

The first and second conductive resin layers 131b and 132b may contain the hydrogen gas and the moisture at the time of plating the first and second nickel plating layers 131c and 132c.

The multilayer ceramic electronic component 100 according to the exemplary embodiment of the present disclosure may be configured so that the hydrogen gas and the moisture distributed on the surfaces of the first and second conductive resin layers 131b and 132b are discharged to the outside through the first and second nickel plating layers 131c and 132c. Therefore, the external electrode swelling defect may be prevented.

For example, the first and second conductive resin layers 131b and 132b may have a structure in which conductive particles such as copper (Cu), nickel (Ni), palladium (Pd), gold (Au), silver (Ag) or lead (Pb) are included in a resin having high flexibility such as a glass or an epoxy resin, and thus may have high flexibility and high conductivity.

Meanwhile, the first and second external electrodes 131 and 132 may further include first and second tin plating layers 131d and 132d disposed at external surfaces of the first and second nickel plating layers 131c and 132c. The first and second tin plating layers 131d and 132d may further improve at least some of structural reliability, easiness of mounting on a substrate, durability against the outside, heat resistance, and equivalent series resistance value.

Meanwhile, the first and second nickel plating layers 131c and 132c may each have a thickness of 0.5 μm or more. Accordingly, the mounting reliability of the first and second external electrodes 131 and 132 may be effectively secured.

In addition, each of the first and second nickel plated layers 131c and 132c may have a thickness smaller than that of each of the first and second base electrode layers 131a and 132a. Accordingly, the reliability of the first and second external electrodes 131 and 132 against costs may be improved, and the warpage endurance may be efficiently secured.

FIG. 4 is a perspective view showing a mounting form of a multilayer ceramic electronic component according to an exemplary embodiment of the present disclosure.

Referring to FIG. 4, the multilayer ceramic electronic component 100 according to the embodiment of the present disclosure may be electrically connected to the substrate 210, including first and second solders 230 connected to the first and second external electrodes 131 and 132, respectively.

For example, the substrate 210 may include first and second electrode pads 221 and 222, and the first and second solders 230 may be disposed on the first and second electrode pads 221 and 222, respectively.

If the vertexes of the ceramic body 110 are round, the first and second solders 230 may be stably connected to the first and second external electrodes 131 and 132 as the first and second solders 230 are filled in an extra space corresponding to the rounded vertexes of the ceramic body 110.

The first and second solders 230 may be further tightly coupled to the first and second external electrodes 131 and 132 according to a reflow process. The multilayer ceramic electronic component 100 according to the exemplary embodiment of the present disclosure may include the nickel plating layer having the nickel fineness of 89% or more to prevent the first and second solder 230 from being disconnected during the reflow.

As set forth above, according to exemplary embodiments of the present disclosure, the multilayer ceramic electronic component may have the improved reliability of the external electrodes and the improved mounting reliability by optimizing the nickel fineness of the nickel plating layers included in the external electrodes.

While exemplary embodiments have been shown and described above, it will be apparent to those skilled in the art that modifications and variations could be made without departing from the scope of the present invention as defined by the appended claims.

1. A multilayer ceramic electronic component, comprising:
a ceramic body including a dielectric layer and first and second internal electrodes stacked to be alternately exposed to one side surface and the other side surface with the dielectric layer disposed therebetween; and
first and second external electrodes disposed on outer surfaces of the ceramic body to be connected to the first and second internal electrodes, respectively,
wherein the first external electrode includes:
a first base electrode layer,
a first nickel plating layer disposed on the first base electrode layer and having a nickel fineness of 89% or more and 93% or less, and
a first tin plating layer disposed directly on the first nickel plating layer having the nickel fineness of 89% or more and 93% or less, and
the second external electrode includes:
a second base electrode layer,
a second nickel plating layer disposed on the second base electrode layer and having a nickel fineness of 89% or more and 93% or less, and
a second tin plating layer disposed directly on the second nickel plating layer having the nickel fineness of 89% or more and 93% or less.

2. The multilayer ceramic electronic component of claim 1, wherein the first and second base electrode layers at least partially contact the outer surfaces of the ceramic body, respectively.

3. (canceled)

4. (canceled)

5. The multilayer ceramic electronic component of claim 1, wherein each of the first and second nickel plating layers has a thickness smaller than that of each of the first and second base electrode layers.

6. The multilayer ceramic electronic component of claim 1, wherein each of the first and second nickel plating layers has a thickness of 0.5 μm or more.

7. (canceled)

8. The multilayer ceramic electronic component of claim 1, wherein an average thickness of the dielectric layer disposed between the first and second internal electrodes exceeds twice that of each of the first and second internal electrodes.

9. The multilayer ceramic electronic component of claim 1, further comprising:
first and second solders connected to each of the first and second external electrodes on a substrate.

10. The multilayer ceramic electronic component of claim 1, wherein the ceramic body has a hexahedral form having eight rounded vertexes.
